(19) United States
(12) Patent Application Publication
(10) Pub. No.: US 2009/0201400 A1
(43) Pub. Date: Aug. 13, 2009

(54) Backside illuminated image sensor with global shutter and storage capacitor

(75) Inventors: Guangbin Zhang, Sunnyvale, CA (US); Tiejun Dai, Santa Clara, CA (US); Hongli Yang, Saratoga, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES, INC., Sunnyvale, CA (US)

(21) Appl. No.: 12/028,659

(22) Filed: Feb. 8, 2008

(51) Int. Cl. H04N 5/335; H01L 27/148

(52) U.S. Cl. 348/296; 257/292; 257/E27.133; 348/E05.091

(57) ABSTRACT

A backside illuminated imaging sensor pixel includes a photodiode region, a pixel circuitry region, and a storage capacitor. The photodiode region is disposed within a semiconductor die for accumulating an image charge. The pixel circuitry region is disposed on the semiconductor die between a frontside of the semiconductor die and the photodiode region. The pixel circuitry region overlaps at least a portion of the photodiode region. The storage capacitor is included within the pixel circuitry region overlapping the photodiode region and is selectively coupled to the photodiode region to temporarily store image charges accumulated thereon.

### TECHNICAL FIELD

This disclosure relates generally to image sensors, and in particular but not exclusively, relates to backside illuminated CMOS image sensors.

### BACKGROUND INFORMATION

For high speed image sensors, it is preferred to use a global shutter to capture fast-moving objects. A global shutter enables all pixels in the image sensor to simultaneously capture the image. For slower moving objects, the more common rolling shutter is used. A rolling shutter captures the image in a sequence. For example, each row within a two-dimensional (“2D”) pixel array may be enabled sequentially, such that each pixel within a single row captures the image at the same time, but each row is enabled in a rolling sequence. As such, each row of pixels captures the image during a different image acquisition window. For slow-moving objects the time differential between each row generates acceptable image distortion. For fast-moving objects, a rolling shutter causes a perceptible elongation distortion along the object's axis of movement. To implement a global shutter, storage capacitors are used to temporarily store the image charge acquired by each pixel in the array while it awaits readout from the pixel array.

FIG. 1 illustrates a conventional frontside illuminated complementary metal-oxide-semiconductor (“CMOS”) imaging pixel 100. The frontside of imaging pixel 100 is the side of substrate 105 upon which the pixel circuitry is disposed and over which metal stack 110 for redistributing signals is formed. The metal layers (e.g., metal layer M1 and M2) are patterned in such a manner as to create an optical passage through which light incident on the frontside of imaging pixel 100 can reach the photosensitive photodiode (“PD”) region 115. The frontside may further include a color filter layer to implement a color sensor and a microlens to focus the light onto PD region 115.

To implement a global shutter, conventional imaging pixel 100 incorporates a storage capacitor 120. In order to enable quick charge transfer between PD region 115 and minimize signal routing, storage capacitor 120 is positioned immediately adjacent to photodiode region 115 within pixel circuitry region 125 along with the remaining pixel circuitry for operating imaging pixel 100. Consequently, storage capacitor 120 consumes valuable real estate within imaging pixel 100 at the expense of PD region 115. Reducing the size of PD region 115 to accommodate storage capacitor 120 reduces the fill factor of imaging pixel 100 thereby reducing the amount of pixel area that is sensitive to light, and reducing low light performance.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 is a cross sectional view of a conventional frontside illuminated imaging pixel.

FIG. 2 is a block diagram illustrating a backside illuminated imaging system, in accordance with an embodiment of the invention.

FIG. 3 is a circuit diagram illustrating pixel circuitry of two 4T pixels within a backside illuminated imaging system, in accordance with an embodiment of the invention.

FIG. 4A is a hybrid cross sectional/circuit illustration of a backside illuminated imaging pixel with a storage capacitor, in accordance with an embodiment of the invention.

FIG. 4B illustrates a multi-layer storage capacitor for use in a backside illuminated imaging pixel, in accordance with an embodiment of the invention.

FIG. 5 is a flow chart illustrating a process for operating a backside illuminated imaging pixel with storage capacitor, in accordance with an embodiment of the invention.

### DETAILED DESCRIPTION

Embodiments of a system and method of operation for a backside illuminated image sensor with global shutter and storage capacitors are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise. The term “overlapping” is defined herein with reference to the surface normal of a semiconductor die. Two elements disposed on a die are said to be “overlapping” if a line drawn through a cross section of the semiconductor die running parallel with the surface normal intersects the two elements.

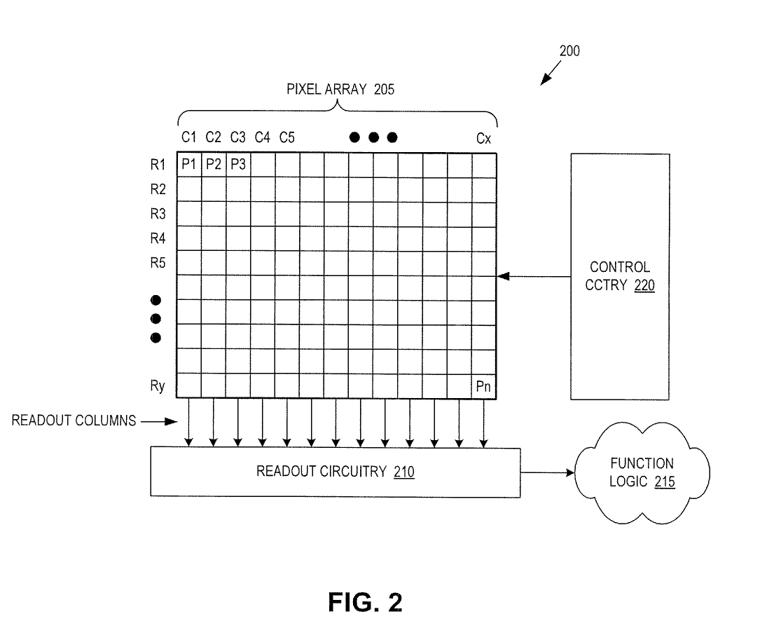

FIG. 2 is a block diagram illustrating a backside illuminated imaging system 200, in accordance with an embodiment of the invention. The illustrated embodiment of imaging system 200 includes a pixel array 205, readout circuitry 210, function logic 215, and control circuitry 220.

Pixel array 205 is a two-dimensional (“2D”) array of backside illuminated imaging sensors or pixels (e.g., pixels P1, P2 . . . , Pn). In one embodiment, each pixel is an active pixel sensor (“APS”), such as a complementary metal-oxide-semiconductor (“CMOS”) imaging pixel. As illustrated, each pixel is arranged into a row (e.g., rows R1 to Ry) and a column (e.g., column C1 to Cx) to acquire image data of a person, place, or object, which can then be used to render a 2D image of the person, place, or object.

After each pixel has acquired its image data or image charge, the image data is readout by readout circuitry 210 and transferred to function logic 215. Readout circuitry 210 may include amplification circuitry, analog-to-digital conversion circuitry, or otherwise. Function logic 215 may simply store the image data or even manipulate the image data by applying post image effects (e.g., crop, rotate, remove red eye, adjust brightness, adjust contrast, or otherwise). In one embodiment, readout circuitry 210 may readout a row of image data at a time along readout column lines (illustrated) or may readout the image data using a variety of other techniques (not illustrated), such as a serial readout or a full parallel readout of all pixels simultaneously.

Control circuitry 220 is coupled to pixel array 205 to control operational characteristic of pixel array 205. For example, control circuitry 220 may generate a shutter signal for controlling image acquisition. In one embodiment, the shutter signal is a global shutter signal for simultaneously enabling all pixels within pixel array 205 to simultaneously capture their respective image data during a single acquisition window. In an alternative embodiment, the shutter signal is a rolling shutter signal whereby each row, column, or group of pixels is sequentially enabled during consecutive acquisition windows.

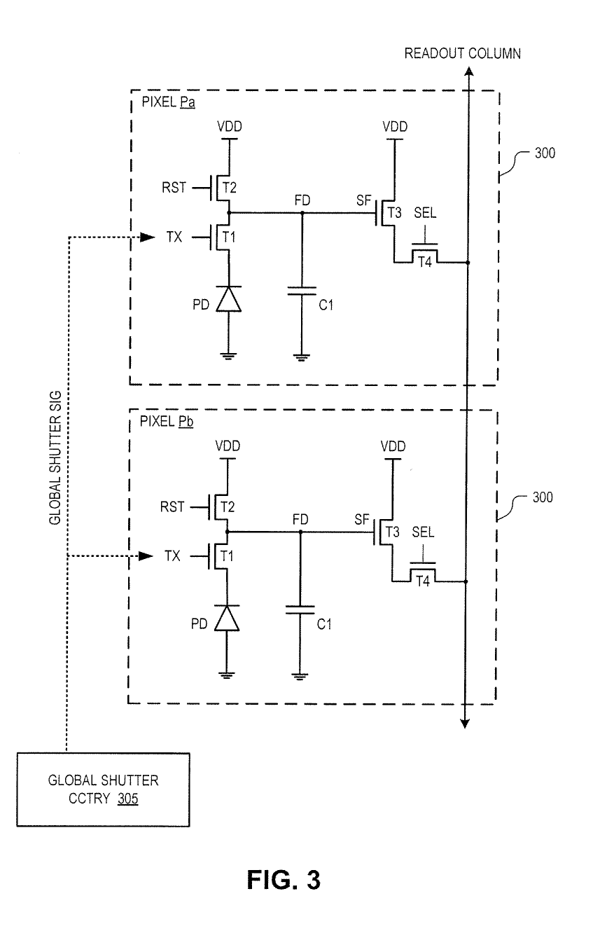

FIG. 3 is a circuit diagram illustrating pixel circuitry 300 of two four-transistor (“4T”) pixels within a backside illuminated imaging array, in accordance with an embodiment of the invention. Pixel circuitry 300 is one possible pixel circuitry architecture for implementing each pixel within pixel array 200 of FIG. 2. However, it should be appreciated that embodiments of the present invention are not limited to 4T pixel architectures; rather, one of ordinary skill in the art having the benefit of the instant disclosure will understand that the present teachings are also applicable to 3T designs, 5T designs, and various other pixel architectures.

In FIG. 3, pixels Pa and Pb are arranged in two rows and one column. The illustrated embodiment of each pixel circuitry 300 includes a photodiode PD, a transfer transistor T1, a reset transistor T2, a source-follower (“SF”) transistor T3, a select transistor T4, and a storage capacitor C1. During operation, transfer transistor T1 receives a transfer signal TX, which transfers the charge accumulated in photodiode PD to a floating diffusion node FD coupled to storage capacitor C1. While floating diffusion node FD has an intrinsic capacitance, it is generally not a sufficient replacement for storage capacitor C1. For example, the size of floating diffusion FD necessary to achieve sufficient capacitance would result in unacceptable leakage current and other nonlinear characteristics.

Reset transistor T2 is coupled between a power rail VDD and the floating diffusion node FD to reset (e.g., discharge or charge the FD to a preset voltage) under control of a reset signal RST. The floating diffusion node FD is coupled to control the gate of SF transistor T3. SF transistor T3 is coupled between the power rail VDD and select transistor T4. SF transistor T3 operates as a source-follower providing a high impedance output from storage capacitor C1. Finally, select transistor T4 selectively couples the output of pixel circuitry 300 to the readout column line under control of a select signal SEL.

In one embodiment, the TX signal, the RST signal, and the SEL signal are generated by control circuitry 220. In an embodiment, where pixel array 205 operates with a global shutter, the global shutter signal is coupled to the gate of each transfer transistor T1 in the entire pixel array 205 to simultaneously commence charge transfer between each pixel's photodiode PD and storage capacitor C1. In one embodiment, the global shutter signal is generated by global shutter circuitry 305 included within control circuitry 220.

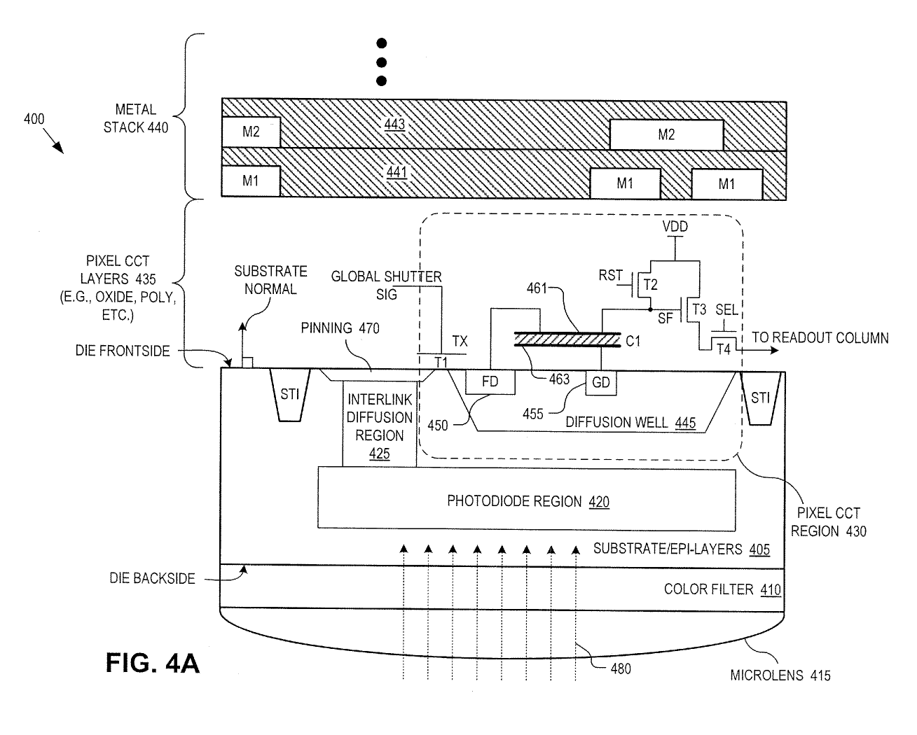

FIG. 4A is a hybrid cross sectional/circuit illustration of a backside illuminated imaging pixel 400 with a storage capacitor, in accordance with an embodiment of the invention. Imaging pixel 400 is one possible implementation of pixels P1 to Pn within pixel array 205. The illustrated embodiment of imaging pixel 400 includes a substrate 405, a color filter 410, a microlens 415, a PD region 420, an interlinking diffusion region 425, a pixel circuitry region 430, pixel circuitry layers 435, and a metal stack 440. The illustrated embodiment of pixel circuitry region 430 includes a 4T pixel (other pixel designs may be substituted) with storage capacitor C1 disposed within a diffusion well 445. A floating diffusion 450 is disposed within diffusion well 445 and coupled between transfer transistor T1 and electrode 461 of storage capacitor C1. An electrode 463 of storage capacitor C1 is coupled to a ground diffusion 455 also disposed within diffusion well 445. The illustrated embodiment of metal stack 440 includes two metal layers M1 and M2 separated by intermetal dielectric layers 441 and 443. Although FIG. 4A illustrates only a two layer metal stack, metal stack 440 may include more or less layers for routing signals over the frontside of pixel array 205. In one embodiment, a passivation or pinning layer 470 is disposed over interlinking diffusion region 425. Finally, shallow trench isolations (“STI”) insulate imaging pixel 400 from adjacent pixels (not illustrated).

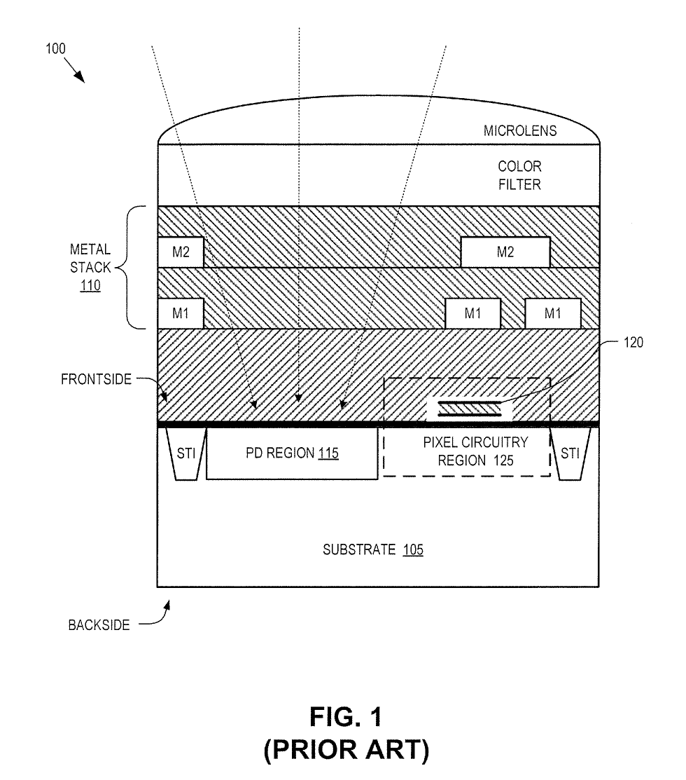

As illustrated, imaging pixel 400 is photosensitive to light 480 incident on the backside of its semiconductor die. By using a backside illuminated sensor, pixel circuitry region 430 can be positioned in an overlapping configuration with photodiode region 420. In other words, pixel circuitry 300 including storage capacitor C1 can be placed adjacent to interlinking diffusion region 425 and between photodiode region 420 and the die frontside without obstructing light 480 from reaching photodiode region 420. By placing storage capacitor C1 overlapping with photodiode region 420, as opposed to side-by-side as illustrated in FIG. 1, photodiode region 420 and storage capacitor C1 no longer compete for valuable die real estate. Rather, storage capacitor C1 can be enlarged to increase its capacitance without detracting from the fill factor of the image sensor. Embodiments of the present invention enable high capacity storage capacitors C1 to be placed in close proximity to their respective photodiode region 420 without decreasing the sensitivity of the pixel. Furthermore, the backside illumination configuration provides greater flexibility to route signals over the frontside of pixel array 205 within metal stack 440 without interfering with light 480. In one embodiment, the global shutter signal is routed within metal stack 440 to all the pixels within pixel array 205.

Another advantage to placing storage capacitor C1 on the opposite side of photodiode region 420 from the light exposed side is increased isolation from the incident photons. Photons reaching storage capacitor C1 can lead to increased leakage current. However, the majority of photons incident on the backside of the die terminate within photodiode region 420. Those photons that penetrate past photodiode region 420 are further blocked by electrode 463 of storage capacitor C1. By electrically coupling electrode 463 to diffusion well 445 via grounding diffusion 455, electrode 463 effectively operates as an isolating ground plane. Electrodes 461 and 463 may be fabricated with a variety of conductive materials include metal, polysilicon, a combination of both, or otherwise.

In one embodiment, grounding diffusion 455 is a doping region having the same conductivity type (i.e., positive or negative dopant profile) as the surrounding diffusion well 445, but with a higher doping concentration. In contrast, floating diffusion 450 is doped with an opposite conductivity type dopant to generate a p-n junction within diffusion well 445 thereby electrically isolating floating diffusion 450.

In one embodiment, substrate 405 is doped with P-type dopants. In this case, substrate 405 and the epitaxial layers grown thereon may be referred to as a P-substrate. In a P-substrate embodiment, diffusion well 445 is a P+ well implant and grounding diffusion 455 is a P++ implant, while photodiode region 420, interlinking diffusion region 425, and floating diffusion 450 are N-type doped. In an embodiment where substrate 405 and the epitaxial layers thereon are N-type, diffusion well 445 and grounding diffusion 455 are also N-type doped, while photodiode region 420, interlinking diffusion region 425, and floating diffusion 450 have an opposite P-type conductivity.

FIG. 4B illustrates a multi-layer storage capacitor C2, in accordance with an embodiment of the invention. In one embodiment, multi-layer storage capacitor C2 may replace storage capacitor C1 within imaging pixel 400 to achieve increased storage capacitance. The illustrated embodiment of multi-layer storage capacitor C2 includes two electrodes 491 and 493 separated by two layers of an insulating dielectric material. Electrodes 491 and 493 may be fabricated of a variety of conductive materials, such as metal or polysilicon, while the separating dielectric may be made of silicon dioxide or other insulating material. Although FIG. 4B illustrates a double stacked capacitor, it should be appreciated that embodiments of multi-layer storage capacitor C2 may include 3, 4, or more electrode stacks to increase the capacitance of C2 while still residing within pixel circuitry region 430 above photodiode region 420.

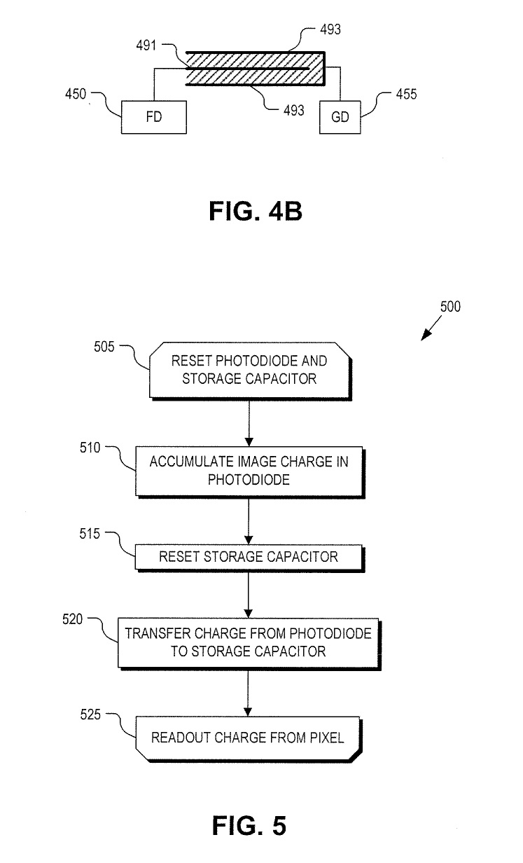

FIG. 5 is a flow chart illustrating a process 500 for operating a backside illuminated imaging pixel 400, in accordance with an embodiment of the invention. Process 500 illustrates the operation of a single pixel within pixel array 205; however, it should be appreciated that process 500 may be sequentially or concurrently executed by each pixel in pixel array 205 depending upon whether a rolling shutter or global shutter is used. The order in which some or all of the process blocks appear in process 500 should not be deemed limiting. Rather, one of ordinary skill in the art having the benefit of the present disclosure will understand that some of the process blocks may be executed in a variety of orders not illustrated.

In a process block 505, photodiode PD (e.g., photodiode region 420) and storage capacitor C1 are reset. Resetting includes discharging or charging photodiode PD and storage capacitor C1 to a predetermined voltage potential, such as VDD. The reset is achieved by asserting both the RST signal to enable reset transistor T2 and asserting the TX signal to enable transfer transistor T1. Enabling T1 and T2 couples photodiode region 420, floating diffusion 450, and electrode 461 to power rail VDD.

Once reset, the RST signal and the TX signal are de-asserted to commence image acquisition by photodiode region 420 (process block 510). Light 480 incident on the backside of imaging pixel 400 is focused by microlens 415 through color filter 410 onto the backside of photodiode region 420. Color filter 410 operates to filter the incident light 480 into component colors (e.g., using a Bayer filter mosaic or color filter array). The incident photons cause charge to accumulate within the diffusion region of the photodiode.

During the image acquisition window while charge is accumulating within photodiode region 420, storage capacitor C1 is once again reset by temporarily asserting the RST signal while the TX signal remains de-asserted (process block 515). This second reset only resets storage capacitor C1 to reduce thermal noise and other stray charge/leakage charge from combining with the image charge.

Once the image acquisition window has expired, the RST signal is again de-asserted and the accumulated charge within photodiode region 420 is transferred via the transfer transistor T1 to storage capacitor C1 by asserting the TX signal (process block 520). In the case of a global shutter, the global shutter signal is asserted simultaneously, as the TX signal, to all pixels within pixel array 205 during process block 520. This results in a global transfer of the image data accumulated by each pixel into the pixel's corresponding storage capacitor C1.

Once the image data is transferred into storage capacitor C1, the TX signal is de-asserted to isolate storage capacitor C1 for readout. In a process block 525, the SEL signal is asserted to transfer the stored image data onto the readout column for output to the function logic 215 via readout circuitry 210. It should be appreciated that readout may occur on a per row basis via column lines (illustrated), on a per column basis via row lines (not illustrated), on a per pixel basis (not illustrated), or by other logical groupings. Once the image data of all pixels has been readout, process 500 returns to process block 505 to prepare the individual storage capacitors C1 for the next image.

The processes explained above are described in terms of computer software and hardware. The techniques described may constitute machine-executable instructions embodied within a machine (e.g., computer) readable medium, that when executed by a machine will cause the machine to perform the operations described. Additionally, the processes may be embodied within hardware, such as an application specific integrated circuit (“ASIC”) or the like.

A machine-accessible or machine-readable medium includes any mechanism that provides (i.e., stores) information in a form accessible by a machine (e.g., a computer, network device, personal digital assistant, manufacturing tool, any device with a set of one or more processors, etc.). For example, a machine-accessible medium includes recordable/non-recordable media (e.g., read only memory (ROM), random access memory (RAM), magnetic disk storage media, optical storage media, flash memory devices, etc.).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An imaging sensor pixel, comprising:
a photodiode region disposed within a semiconductor die for accumulating an image charge;
a pixel circuitry region disposed within the semiconductor die between a frontside of the semiconductor die and the photodiode region, the pixel circuitry region overlapping at least a portion of the photodiode region;
an interlinking diffusion region disposed within the semiconductor die, the interlinking diffusion region coupled to the photodiode region and extending towards the frontside of the semiconductor die; and
a storage capacitor included within the pixel circuitry region overlapping the photodiode region and selectively coupled via the interlinking diffusion region to the photodiode region to temporarily store the image charge accumulated thereon.

2. The imaging sensor pixel of claim 1, wherein the imaging sensor pixel comprises a complimentary metal-oxide-semiconductor (“CMOS”) backside illuminated imaging sensor pixel.

3. The imaging sensor pixel of claim 2, wherein the semiconductor die comprises a P-type silicon substrate and the pixel circuitry region comprises a P-well diffusion region disposed between the photodiode region and the frontside of the semiconductor die.

4. The imaging sensor pixel of claim 1, wherein the storage capacitor comprises:
a first electrode selectively coupled to the interlinking diffusion region;
a second electrode; and
a dielectric insulating layer disposed between the first and second electrodes.

5. The imaging sensor pixel of claim 4, wherein the first and second electrodes are made of a material selected from a group including polysilicon or metal.

6. The imaging sensor pixel of claim 4, wherein the storage capacitor comprises a multilayer stacked capacitor having at least two overlapping dielectric insulating layers.

7. The imaging sensor pixel of claim 4, further comprising:
a grounding diffusion region disposed within the pixel circuitry region and coupled to the second electrode to ground the second electrode, the grounding diffusion region having a same conductivity type as a substrate of the semiconductor die; and
a floating diffusion disposed within the pixel circuitry region and coupled to the first electrode, the floating diffusion having an opposite conductivity type as the substrate.

8. The imaging sensor pixel of claim 7, wherein the imaging sensor pixel comprises a four transistor (“4T”) pixel design having all four transistors disposed within the pixel circuitry region, the 4T pixel design comprising:
a transfer transistor coupled between the interlinking diffusion region and the floating diffusion;
a reset transistor coupled to the first electrode to reset the storage capacitor and the floating diffusion;
a source-follower transistor coupled to output the image charge from the storage capacitor; and
a select transistor to select the imaging sensor pixel from other imaging sensor pixels for readout.

9. The imaging sensor pixel of claim 2, further comprising:
a microlens disposed on a backside of the semiconductor die below the photodiode region and optically aligned to focus light received from the backside onto the photodiode region; and
a color filter disposed between the microlens and the photodiode region to filter the light.

10. A method of operation of a pixel array including a plurality of pixels wherein each of the pixels includes a backside illuminated complimentary metal-oxide-semiconductor (“CMOS”) imaging sensor, for each of the pixels, the method comprising:
accumulating charge within a photodiode region of the pixel generated by light incident upon a backside of the pixel; and
transferring the charge accumulated within the photodiode region to a storage capacitor, wherein the storage capacitor is positioned on a frontside of the pixel opposite the backside and overlaps the photodiode region.

11. The method of claim 10, further comprising for each pixel:
resetting the photodiode region and the storage capacitor prior to accumulating the charge by temporarily enabling a transfer transistor coupled between the photodiode region and a first electrode of the storage capacitor and by temporarily enabling a reset capacitor coupled between a voltage rail and the first electrode of the storage capacitor; and
resetting the storage capacitor again between accumulating the charge and transferring the charge to the storage capacitor by enabling the reset capacitor while disabling the transfer transistor.

12. The method of claim 11, further comprising for each pixel:
reading out the charge stored on the storage capacitor by temporarily enabling a select transistor.

13. The method of claim 10, wherein transferring the charge accumulated within the photodiode region for each pixel comprises enabling a global shutter signal to commence transferring the charge simultaneously for all pixels within the pixel array.

14. The method of claim 10, further comprising:
focusing the light onto the photodiode region with a microlens disposed on the backside;
grounding a first electrode of the storage capacitor to a grounding diffusion formed in a doped well disposed in an epitaxial layer,
wherein transferring the charge accumulated within the photodiode region to the storage capacitor includes transferring the charge through a transfer gate to a floating diffusion disposed within the doped well having an opposite conductivity type as the doped well, the floating diffusion coupled to a second electrode of the storage capacitor,
wherein the doped well is disposed within the epitaxial layer overlapping the photodiode region between a frontside of the pixel and the photodiode region.

15. An imaging system comprising:
a backside illuminated array of imaging pixels wherein each imaging pixel includes:
a photodiode region for accumulating an image charge;
a storage capacitor coupled to temporarily store the image charge accumulated by the photodiode, the storage capacitor disposed between a frontside of the imaging pixel and the photodiode region;
a transfer transistor to selectively couple the photodiode region to the storage capacitor;
control circuitry coupled to the backside illuminated array of imaging pixels to generate a shutter signal for selectively enabling the transfer transistor of one or more of the imaging pixels; and
readout circuitry coupled to the backside illuminated array of imaging pixels to selectively readout the image charge.

16. The imaging system of claim 15, wherein the shutter signal comprises a global shutter signal coupled to simultaneously enable each transfer transistor within the backside illuminated array of imaging pixels to simultaneously capture an image with all the imaging pixels.

17. The imaging system of claim 15, wherein the storage capacitor and transfer transistor are disposed within a diffusion well formed over the photodiode region, wherein each imaging pixel further includes:
a floating diffusion having an opposite conductivity type as the diffusion well coupled to the transfer transistor and coupled to a first electrode of the storage capacitor; and
a grounding diffusion having a similar conductivity type as the diffusion well coupled to a second electrode of the storage capacitor.

18. The imaging system of claim 15, wherein the backside illuminated array of imaging pixels further includes:
a plurality of microlenses disposed on a backside of the array of imaging pixels and each aligned to focus light on a corresponding pixel; and
a metal stack including two or more metal layers disposed on a frontside of the array of imaging pixels for routing signals.

19. The imaging system of claim 15, wherein the storage capacitor comprises a multilayer stacked capacitor having at least two overlapping dielectric insulating layers.

20. The imaging system of claim 15, wherein each pixel comprises a four transistor (“4T”) pixel design including:
the transfer transistor coupled between the photodiode region and a floating diffusion;
a reset transistor coupled to a first electrode of the storage capacitor to reset the image charge on the storage capacitor;
a source-follower transistor coupled to output the image charge from the storage capacitor; and
a select transistor to select the imaging sensor pixel from other imaging sensor pixels for readout.
